(19) United States
(12) Patent Application Publication
(10) Pub. No.: US 2026/0119767 A1
(43) Pub. Date: Apr. 30, 2026

(54) SYSTEM AND METHOD FOR SEMICONDUCTOR FABRICATION

(71) Applicant: TAIWAN SEMICONDUCTOR MANUFACTURING COMPANY LTD., HSINCHU (TW)

(72) Inventors: TUN SHENG TAN, HSINCHU (TW); ANJAN DWARAKNATH, HSINCHU (TW)

(21) Appl. No.: 18/925,090

(22) Filed: Oct. 24, 2024

(51) Int. Cl. G06F 30/367; G06F 30/398

(52) U.S. Cl. CPC G06F 30/367; G06F 30/398

(57) ABSTRACT

A method, includes steps of receiving an aerial image associated with a design layout, wherein the aerial image comprises a first contour corresponding to the design layout; determining a modeling parameter set associated with the first contour based on historical data in a database; and converting the aerial image into a photoresist image comprising a second contour associated with the design layout according to the modeling parameter set.

### BACKGROUND

In order to detect design errors or defects as early as possible, circuit designers use computer-aided circuit design tools, which have become widely accepted in the semiconductor industry, to assist in identifying potential defects. However, as circuit complexity and device density continue to increase, the software procedures involved in circuit design and verification now consume a great deal of time and resources. Therefore, it is necessary to improve the design flow for reducing design cycle time while maintaining design quality.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic block diagram of an integrated circuit (IC) manufacturing system, in accordance with some embodiments of the present disclosure.

FIG. 2 is a schematic view of a lithographic tool, in accordance with some embodiments of the present disclosure.

FIG. 3A a schematic plan view of a mask, in accordance with some embodiments of the present disclosure.

FIG. 3B is a schematic diagram illustrating an example aerial image associated with the mask shown in FIG. 3A, in accordance with some embodiments of the present disclosure.

FIG. 3C is a schematic diagram illustrating an example photoresist layer associated with the mask shown in FIG. 3A, in accordance with some embodiments of the present disclosure.

FIG. 4 is a shown a contour of a feature, in accordance with some embodiments of the present disclosure.

FIG. 5A shows a critical dimension gauge error between a first contour and a second contour, in accordance with some embodiments of the present disclosure.

FIG. 5B shows an edge placement gauge error between a first contour and a second contour, in accordance with some embodiments of the present disclosure.

FIG. 6 is a flowchart showing a method for semiconductor fabrication, in accordance with some embodiments of the present disclosure.

FIG. 7 is a schematic view of a design layout, in accordance with some embodiments of the present disclosure.

FIG. 8 shows an aerial image, in accordance with some embodiments of the present disclosure.

FIG. 9 schematic block diagram of system for converting an aerial image to a photoresist image, in accordance with some embodiments of the present disclosure.

FIG. 10 shows auxiliary images, in accordance with some embodiments of the present disclosure.

FIG. 11 illustrates a transformation of a portion of a first contour to a portion of a second contour, in accordance with some embodiments of the present disclosure.

FIG. 12 shows photoresist images, in accordance with some embodiments of the present disclosure.

FIG. 13 is a schematic diagram of a system implementing the lithography methods discussed above, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

Embodiments of disclosure includes systems, computer programs and methods employing a simulation model to simulate a pre-development photoresist image associated with a proposed design layout based on a parameter set corresponding to existing design layouts and photoresist images, corresponding to the existing design layout. The simulation model is constructed in mathematical formula to simulate the pre-development photoresist image when formed on a semiconductor wafer through an exposure operation. The pre-development photoresist image is a simulation of an image of an exposed photoresist layer (also referred to as an undeveloped photoresist layer) on the semiconductor wafer, wherein the exposed photoresist layer refers to a photoresist layer undergoes an exposure operation using the proposed design layout and before performing a developing operation.

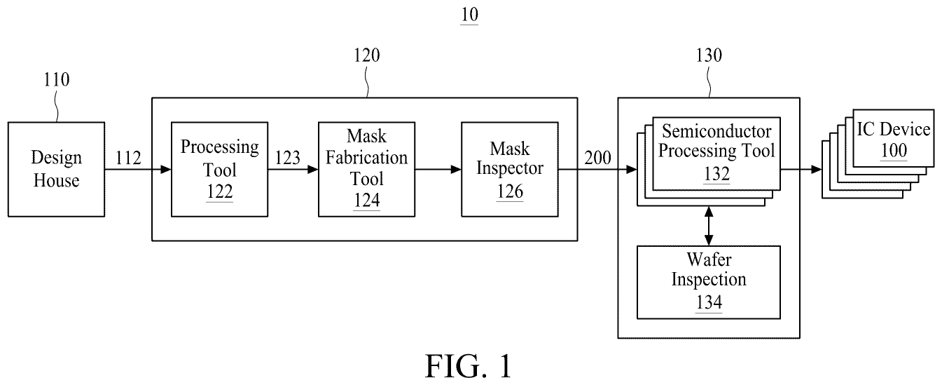

FIG. 1 is a schematic block diagram of an integrated circuit (IC) manufacturing system 10, in accordance with some embodiments of the present disclosure. Referring to FIG. 1, in some embodiments, the IC manufacturing system 10 is configured to manufacture IC devices 100 though a plurality of entities, such as a design house 110, a mask house 120, and an IC manufacturer (i.e., a fab) 130. The entities in the IC manufacturing system 10 are linked by a communication channel, e.g., a wired or wireless channel, and interact with one another through a network, e.g., intranet or the Internet. In an embodiment, the design house 110, the mask house 120, and the fab 130 belong to a single entity. In another embodiments, the design house 120, the fab 130 are operated by independent parties.

The design house 110, which may include one or more design teams, generates a design layout 112 for the IC device 100. The design layout 112 may include descriptions of various geometrical patterns designed for performing specific functions that conform to the performance and manufacturing specifications. The geometrical patterns may correspond to patterns of metal, dielectric, or semiconductor layers that form various components of the IC device 100 to be fabricated. The various layers collectively form various circuit features of the IC device 100. For example, various portions of the design layout 112 may include circuit features such as an active region, a gate electrode, source and drain regions, and metal lines or vias of an interlayer interconnection which are to be formed within a semiconductor substrate (e.g., a silicon wafer) and various material layers disposed on the semiconductor substrate.

In an embodiment, the design house 120 operates a design procedure to generate the design layout 112. The design procedure may include, but is not limited to, logic design, physical design, pre-layout simulation, placement and routing, timing analysis, parameter extraction, design rule check, and post-layout simulation. Computer-aided design (CAD) software or programs may be used in the design procedure. The design layout 112 may be converted from description texts into their visual equivalents to show a physical layout of the depicted patterns, such as the dimensions, shapes and locations thereof. In an embodiment, the design layout 112 can be expressed in a computer-aided format such as a graphic design system file format (such as GDS or GDSII) or a design framework file format (such as DFII). The design house 110 may transmit the design layout 112 to the mask house 120, for example, via the network connection described above.

The mask house 120 may use the design layout 112 to manufacture one or more lithographic masks 200 to be used for fabrication of the various layers of the IC device 100. A lithographic mask 200 (hereinafter referred to “mask 200”) is used in a lithography operation to pattern a semiconductor substrate (such as a silicon wafer) or material layer on the semiconductor substrate. In some embodiments, the mask house 120 includes a processing tool 122, a mask fabrication tool 124 (e.g., a mask writer), and a mask inspector 126.

In some embodiments, the processing tool 122 performs a data preparation, in which the design layout 112 is translated into machine readable instruction for the mask fabrication tool 122. For example, the processing tool 122 generates a mask layout 123 that corresponds to the design layout 112 and complies with particular characteristics and/or requirements of the mask fabrication tool 124 to generate the mask as desired. The mask layout 123 may be generated by fracturing the design layout 112 into elementary features. For example, the design mask 112 may be fractured into sequences of polygons (such as rectangles, trapezoids, or triangles) when the mask fabrication tool 124 uses a variable-shaped beam (VSB) method for making the mask 200. For another example, the design mask 112 may be fractured into a plurality of characters in a stencil when the mask fabrication tool 124 uses a character projection (CP) method for making the mask 200. The fracturing of the design layout 112 may be implemented according to various factors, such as circuit feature geometry, pattern density differences, and/or critical dimension (CD) differences, and mask features are defined based on methods implemented by the mask fabrication tool 124. The data preparation may include an optical proximity correction (OPC). The OPC is a lithography enhancement technique. The OPC is utilized to modify shapes of the mask feature to compensate for diffraction or other operation effects so that the shape of the mask feature as formed in the final integrated circuit closely matches the shape of the circuit feature in the design layout 112.

In some embodiments, the mask fabrication tool 124 is configured to fabricate the mask 200 based on the mask layout 123 provided by the processing tool 122. The mask fabrication tool 124 may perform various lithography operations for fabricating the mask 200. For example, the lithography operations includes transferring the mask layout 123 to the mask material layer. The mask material layer may be an absorption layer, a phase shifting material layer, an opaque material layer, a portion of a mask substrate, and/or other suitable mask material layer. In some embodiments, the transferring of the mask layout to the mask material layer includes performing an exposure operation and a developing operation. During the exposure operation, a radiation beam that is shaped based on the mask layout 123 is steered onto a photoresist layer on the mask material layer. Since the photoresist layer is sensitive to the radiation beam, exposed portions of the photoresist layer chemically change. Exposed (or non-exposed) portions of the photoresist layer are dissolved during the developing operation depending on characteristics of the photoresist layer and characteristics of a developing solution used in the developing operation. The radiation beam may be an electron-beam (e-beam), multiple e-beams, an ion beam, a laser beam or other suitable writer source may be used to transfer the patterns.

After development, the patterned photoresist layer includes a photoresist pattern that corresponds to the mask layout 123. The photoresist pattern is then transferred to the mask material layer by any suitable process to form a final mask feature in the mask material layer. For example, the mask fabrication may include performing an etching operation to remove portions of the mask material layer not protected by the photoresist pattern. After the final mask feature is formed, the photoresist pattern is removed, for example, in an ashing and/or wet strip operation.

In some embodiments, the mask inspector 126 performs a checking procedure to determine if any defects, exist in the fabricated mask 200. If any defects are detected, the mask 200 may be cleaned or the design layout for the formation of the mask 200 may be modified.

The fab 130 uses the mask(s) 200 fabricated by the mask house 120 to fabricate the IC device 100. The fab 130 includes semiconductor processing tools 132 configured to execute various manufacturing operations on a semiconductor wafer and material layers on the semiconductor wafer such that the IC device 100 is fabricated in accordance with the mask(s) 200. The semiconductor processing tool 132 may be operable to receive the mask 200 and yield manufactured features based on the mask layout. The manufacturing operations includes, but not limited to, deposition, lithography, etch, thermal oxidation, ion implantation, and planarization operation. In some embodiments, a manufacturing operation is implemented that uses a mask 200 to fabricate a portion of IC device 100 on the semiconductor wafer. For example, a lithography is implemented to transfer a pattern defined in a mask 200 to a photosensitive layer by selective exposure of the photosensitive layer applied on the semiconductor wafer or the material layer, in order to form a patterned photosensitive layer for other manufacturing operations, such as etching, deposition, or ion implantation. The fab 130 performs the manufacturing operation numerous times using various masks 200 to complete the fabrication of IC device 100.

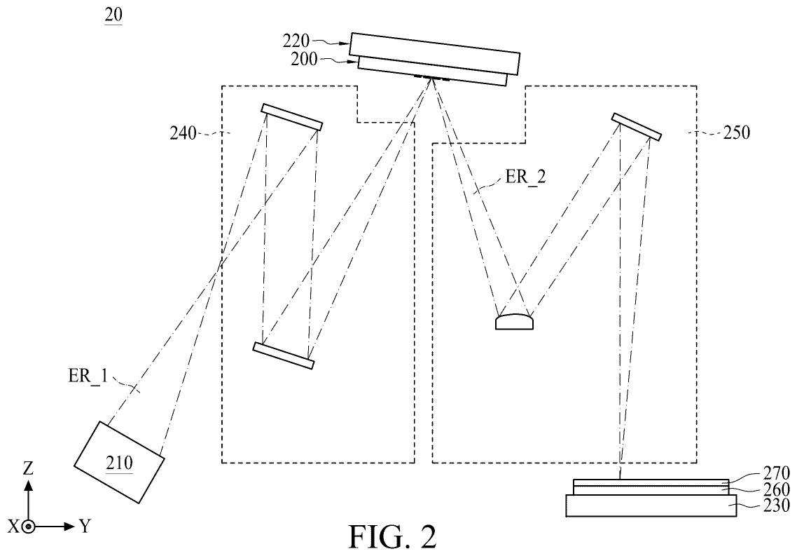

FIG. 2 is a schematic view of a lithography tool 20 in accordance with some embodiments of the present disclosure. Referring to FIGS. 1 and 2, the lithography tool 20 is a semiconductor processing tool that can be used, for example, in the manufacture of the IC device 100. In some embodiments, the lithography tool 20 performs a lithography operation. In the lithography operation, a photosensitive layer 270 is formed on a substrate 260, and the photosensitive layer 270 is subjected to an exposure operation via a mask 200.

In some embodiments, the lithography tool 20 includes a radiation source 210, a mask stage 220, a substrate stage 230, an illumination optical module 240, and a projection optical module 250. The radiation source 210 is configured to generate the electromagnetic radiation ER_1. The radiation source 210 may be any suitable optical source, such as an extreme ultraviolet (EUV) source. The EUV source may generate an EUV radiation having a wavelength between 1 nm and about 100 nm. In some embodiments, the EUV source generates the EUV radiation with a wavelength centered at about 13.5 nm. In some embodiments, the mask stage 220 secures the mask 200 and provides accurate positioning and movement of the mask 200 during the exposure operation. In some embodiments, the substrate stage 230 supports the substrate 260 and is capable of moving the substrate 260 with respect to the mask 200. The mask stage 220 is operable to move the mask 200 in one or more directions as required for proper alignment of the mask 200 relative to the substrate 260.

In some embodiments, the illumination optical module 240 is used to direct the electromagnetic radiation ER_1 generated by the radiation source 210 to the mask 200. In some embodiments, the projection optical module 250 directs the patterned electromagnetic radiation ER_2, carrying the image of the pattern on the mask 200, onto the photosensitive layer 270. In embodiments where the lithography tool 20 includes the EUV source, the illumination optical module 240 and the projection optical module 250 include various reflective optical components such as flat mirrors and/or multiple mirrors including reflective surface with convex and concave spherical shapes or aspheric shapes.

During the exposure operation, a portion of the mask 200 is illuminated by the electromagnetic radiation ER_1. The illumination optical module 240 may be utilized to uniformize the intensity distribution of the electromagnetic radiation ER_1. The illumination optical module 240 may serve to shape the contour of the electromagnetic radiation ER_1 emitting from the radiation source 210. For example, when the electromagnetic radiation ER_1 passes through the illumination optical module 240, it is shaped into a designed profile. It is therefore the patterned electromagnetic radiation ER_2 that has the corresponding profile. The projection optical module 250 directs the patterned electromagnetic radiation ER_2, carrying an image of an irradiated portion of the mask 200, onto the photosensitive layer 270. The patterned electromagnetic radiation ER_2 may cause a chemical transformation in the selected areas of the photosensitive layer 270. In a subsequent development step, the selected areas or non-selected areas can be removed from the substrate 260. In such manners, the pattern of the mask 200 is transferred to the photosensitive layer 270 and thus a patterned photosensitive layer is formed. Although the depicted embodiment shown in FIG. 2 illustrates a reflective-type lithography tool 20, other types of lithography tools, e.g., a transmissive-type lithography tool, are also within the contemplated scope of the present disclosure,

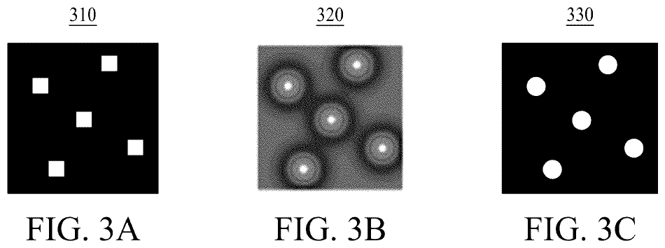

The exposure operation may uses the mask 200 including, in a plan view, a pattern 310 shown in FIG. 3A. FIG. 3B depicts an example aerial image 320. The aerial image 320 is a two-dimensional (2D) image that indicates the intensity distribution of the patterned electromagnetic radiation ER_2 as various contours obtained from measurements from metrology. The aerial image 320 may be generated via experimental measurements, for example, using an aerial image measurement system (AIMS). The AIMS is essentially an optical illumination system of a lithography tool which arranges a camera (such as charge coupled device) at the position of the substrate 260 in order to measure the aerial image generated by the mask 200. In some embodiments, the aerial image 320 is an actual image.

FIG. 3C depicts an example photoresist image 330. The real photoresist image 330 may indicate a spatial distribution of the patterned photosensitive layer that is actually formed on the substrate 260. The real photoresist image may be a post-development image. In some embodiments, the real photoresist image 330 is obtained from an inspection tool, such as a scanning electron microscope (SEM) tool. The aerial image 320 is acquired using a set of parameters associated with a lithography operation for generating the patterned photosensitive layer. The parameters associated with the lithography operation (also referred to as exposure parameters) includes, but are not limited to, the wavelength of radiation provided by the radiation source 210 (also referred to as the illumination wavelength), the numerical aperture (NA) of the lithography tool 20, the coherence value of the lithography tool 20, the defocus, the exposure level, substrate conditions, and possibly imperfections of the lithography tool 20 such as aberrations or flare.

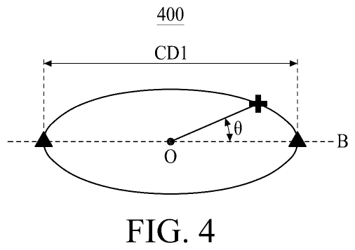

The real photoresist image 330 may be processed to extract contours that describe the edges of objects, representing structural features, in the image. These contours are then quantified via metrics, such as critical dimension (CD). FIG. 4 shows a contour 400 provided with gauges for measuring the CD and an edge placement (EP) thereof, in accordance with some embodiments of the present disclosure. Referring to FIG. 4, the contour 400 has an ellipse shape. The gauges may correspond to points that intersect with the contour 400, wherein the points are illustrated to have a triangular or cross shape for convenience of explanation and example embodiments are not limited thereto. For example, the gauge for measuring the CD (hereinafter referred to “CD gauge”) of the contour 400 has a triangular shape, and the gauge for measuring the EP (hereinafter referred to “EP gauge”) has a cross shape.

The gauges may be used for representing geometric dimensions of the contour 400. For example, the CD is defined as a distance between two CD gauges on the contour 400. The gauges may be used for determining a position of one edge point of contour 400 such as the EP gauge. In some embodiments, the EP gauge is expressed as a data point on the contour 400 at an angle θ between an axis B-O and a line connecting an original point O and the EP gauge.

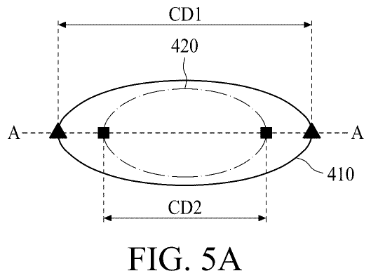

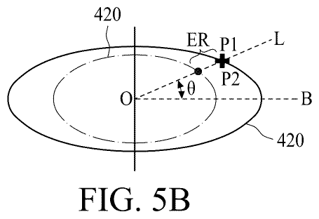

FIGS. 5A and 5B show the relationships between a first contour 410 and a second contour 420 in accordance with some embodiments of the present disclosure. Referring to FIG. 5A, the first and second contours 410 and 420 have ellipse shapes. The gauges having a triangular shape are referred to as first CD gauges and used for representing the critical dimension CD1 of the first contour 410. The first CD gauges may intersect with the major (longitudinal) axis A-A of the first contour 410. The gauges having a square shape are referred to as second CD gauges and used for representing the critical dimension CD2 of the second contour 420. The second CD gauges may intersect with the major (longitudinal) axis A-A of the second contour 410. A CD gauge error is defined as a difference between the critical dimension CD1 of the first contour 410 and the critical dimension CD2 of the second contour 420.

Referring to FIG. 5B, the gauge having a cross shape (hereinafter referred to as a “cross gauge”) is referred to as a first EP gauge and used for representing the edge placement of the first contour 410. The gauge having a circular shape is referred to as a second EP gauge and used for representing the edge placement EP2 of the second contour 410. The first EP gauge and the second EP gauge intersect a line L having an angle θ with respect with the axis B-O. In some embodiments, an EP gauge error ER is defined as a displacement between the first edge placement EP1 and the second edge placement EP2.

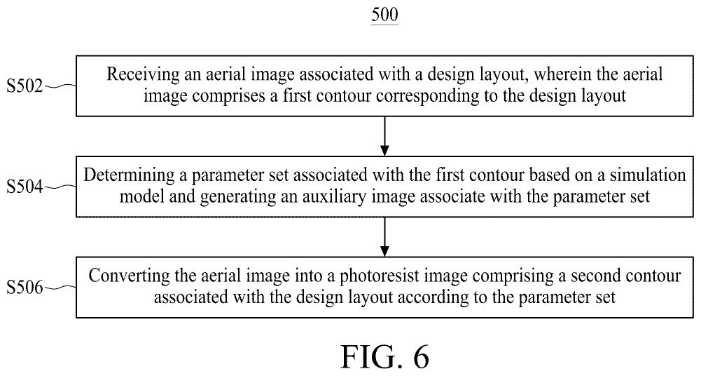

FIG. 6 is a flowchart showing a method 500 according to aspects of one or more embodiments of the present disclosure. Referring to FIG. 6, the method 500 includes a step S502 of receiving an aerial image, wherein aerial image is associated with a design layout; a step S504 of determining a parameter set associated with a contour of the aerial image based on a simulation model; and a step S506 of converting the aerial image into a photoresist image comprising a second contour associated with the design layout according to the parameter set. The method 500 is described for a purpose of illustrating concepts of the present disclosure and is not intended to limit the present disclosure. Additional operations can be provided before, during, and after the method described above and illustrated in FIG. 5, and some operations described in the method 500 can be replaced, eliminated, or moved around for additional embodiments of the method 500.

Referring to FIGS. 6 to 8, the method 500 begins at step S502, in which an aerial image 810 is received. In some embodiments, the aerial image 810 is associated with a design layout 800 of a mask. The design layout 800 includes geometrical patterns corresponding to circuit features to be integrated onto a silicon wafer. In some embodiments, the design layout 800 includes a metal line pattern defining a plurality of metal lines 802 configured to form a portion of an interconnect lines for an IC device.

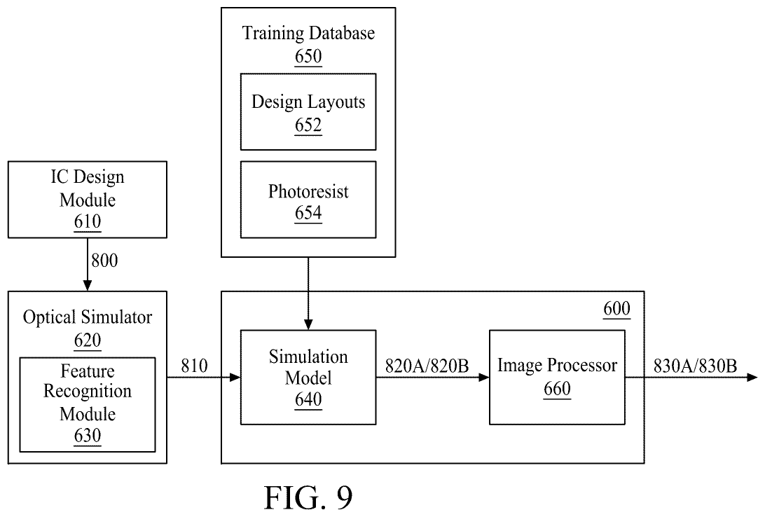

Referring to FIG. 9, the design layout 800 may be output from an IC design module 610. In some embodiments, the design layout 800 of the mask may be generated using one or more computer-aided design (CAD) software programs. The CAD programs follow a set of predetermined design rules in order to generate masks. These design rules are set by taking into consideration the processing and design limitations. For example, the design rules define the space tolerance between circuit features (such as a gate electrode, source and drain regions, etc.) or interconnect lines, so as to ensure that the circuit features or the interconnect lines do not interact with one another in an undesired manner.

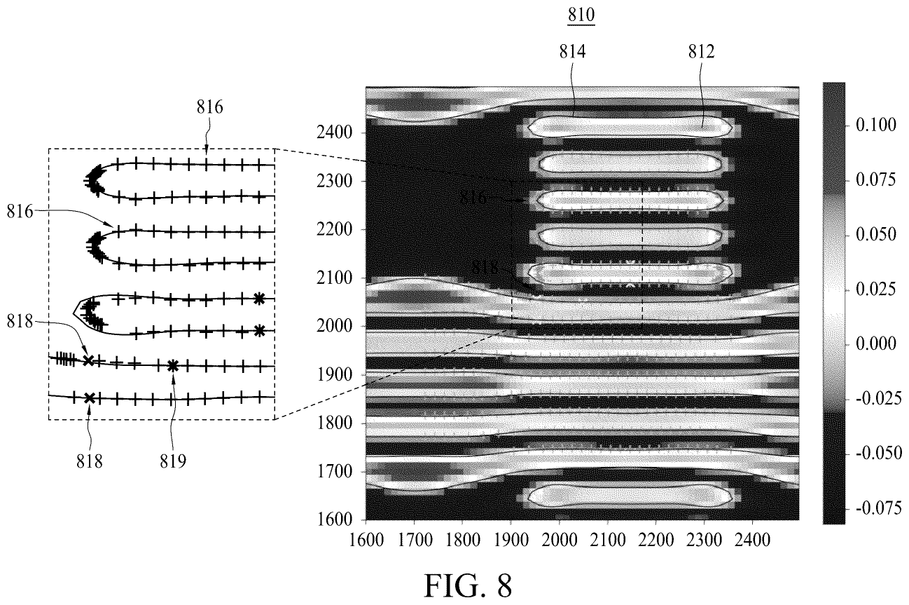

Referring to FIGS. 8 and 9, in some embodiments, the aerial image 810 is a simulated image that is generated based on the design layout 800. The aerial image 810 may be generated using a lithographic simulation to determine the optical intensity distribution on a photoresist layer which is exposed via the design layout 800. The lithographic simulation may be performed with an optical simulator 620. The optical simulator 620 simulates an exposure operations that will be implemented in a fab (such as the fab shown in FIG. 1) to manufacture the IC device 100. In some embodiments, the optical simulator 620 is configured to simulate optical effects of an actual lithography tool (such as the lithography tool 20 shown in FIG. 2) so as to generate the aerial image 810 corresponds to the electromagnetic radiation patterned via the design layout and transferred onto the photoresist layer. In the optical simulator 620, the design layout is analyzed and a mathematical representation is therefore developed that shows the features of the design layout that will be printed onto the photoresist layer. In some embodiments, the aerial image is represented with an array of pixels along with corresponding optical intensities.

The optical simulator 620 may incorporate a set of exposure parameters of the actual lithography tool. The aerial image 810 may represent the estimation of the design layout 800 that is generated by the exposure operation using the design layout 800 under conditions specified by the exposure parameters. In some embodiments, the aerial image 810 may include changes to the intensity distribution of the electromagnetic radiation and/or phase distribution caused by projection optics of the lithography tool.

The optical simulator 620 may include a feature recognition module 630 configured to identify features 812 in the aerial image 810. The features 812 may correspond to the metal lines in the design layout 800. The feature recognition module 630 may be further configured to define a contour 814 of each feature 812 (e.g., the first contour) in the aerial image 810. In an embodiment, the contour 814 refer to an outline of a feature in the aerial image 810. The contour 814 is identified based on a change of intensities of the pixels in the aerial image 810. Image analysis techniques may be used to identify the contour 814 in the aerial image 810. The changes of the intensities of the pixels may occur in a neighborhood of the outlines of the features 812 in the aerial image 810. For example, when a group of pixels show a continuous intensity change, the pixel having the pixel intensity immediately exceeding a threshold (i.e., an intensity above or below a defined value) can be identified as forming the outline (i.e., the contour) of the feature 812. The optical simulator 610 may be executed on a processor or a computer. The aerial image 810 is then transmitted to a simulation model 640.

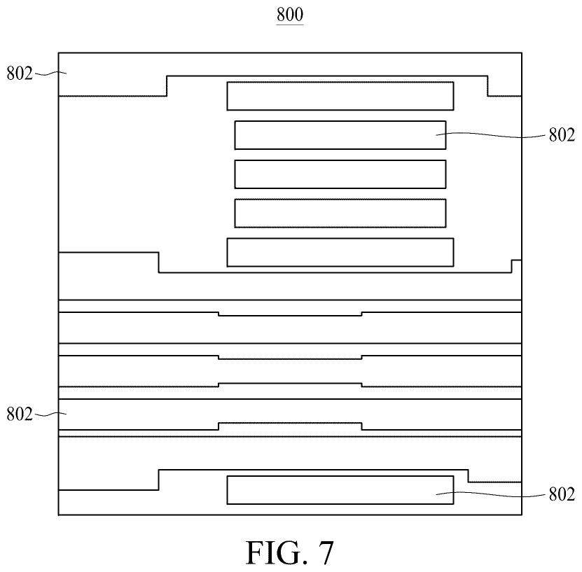

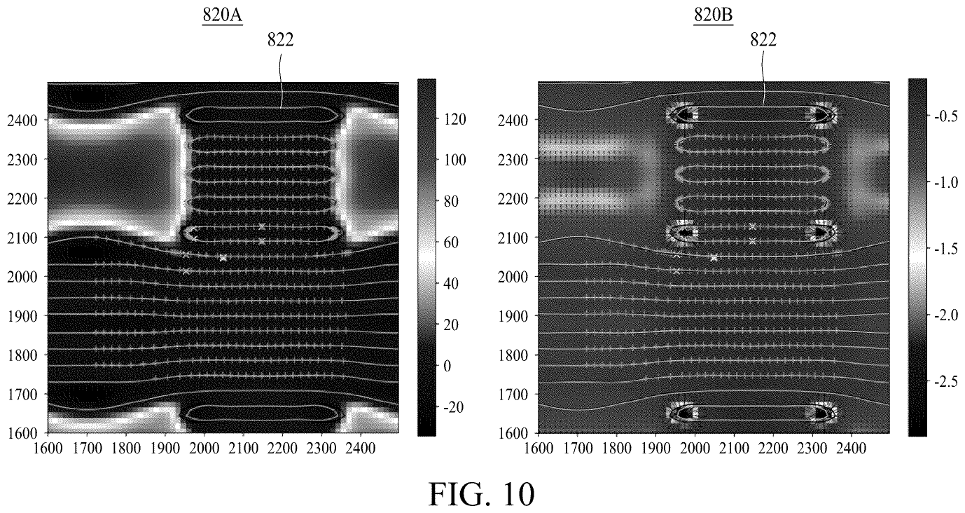

Referring to FIGS. 6 and 7, the method 500 continues with the step S504, in which a parameter set associated with the contour 814 is determined based on a simulation model 640. The simulation model 640 may include a well-trained machine learning model that is configured with a predetermined model structures and associated model parameters. When the simulation model is a well-trained model, it can be utilized to predict a set of output data given a set of input data. In the depicted embodiment, the aerial image 810 serves as the input data for the simulation model 640, and the simulation model 640 generates an auxiliary image 820A or 820B as shown in FIG. 10 as the output data.

The model parameters of the simulation model 640 may be trained before the simulation model 640 is used to perform the prediction task. In some embodiments, the simulation model 640 is configured to train the parameter set that includes information on the changes in critical dimensions and edge placements of the existing or historical contours, and such information may benefit predict actual changes in critical dimensions and edge placements of the contours 814 of the aerial image 810 in order to generate a simulated photoresist image with improved image accuracy in terms of the critical dimension and the edge placement. The simulation model 640 may be established based on training data including existing or historical design layouts 652 and at least one photoresist images 654 corresponding to the existing or historical design layout 652. The training data is used as input at the training stage and the contour variation between the existing design layouts and the photoresist images 654 is learned, trained and saved in the model parameters of the simulation model 640.

The parameter set associated with the auxiliary image 820A/820B is calculated in the simulation model 640 based on well-trained model parameters that may be provided from a training database 650. The training data used to generate the model parameters may include various existing design layouts 652 and photoresist images 654 corresponding to the existing design layouts 652. In some embodiments, the photoresist image 654 represents a photoresist pattern on a substrate. For example, the photoresist image 654 illustrates topography of the photoresist pattern on the substrate. The photoresist images 654 may be post-development images acquired by after-development inspection (ADI) system, such as a scanning electron microscope. The photoresist images 654 may be SEM images. In alternative embodiments, the photoresist images 654 represents an exposed but undeveloped photoresist pattern on the substrate.

The simulation model 640 may include an artificial neural network (ANN) configured to predict the parameter set in response to the ANN with the model parameters thereof. In some embodiments, the predicted parameter set identifies the distribution of gauges in different regions (e.g., line-end regions, line-to-space regions) on the aerial image 810, in order to predict the movement of the contour, for example, on a pixel-by-pixel basis. For example, the parameter in the parameter set with a higher value means the (CD or EP) gauges will tend to move apart from each other for the contour movement between the aerial image and the photoresist image, whereas the parameter in the parameter set with a lower value means the gauges will tend to be move close to each other for the contour movement between the aerial image and in photoresist image.

The CD or EP gauges may be formed as makers overlaid on feature 812 in the aerial image 810 in order to provide assessment of the feature dimensions, e.g., geometric properties of the feature 812. In an embodiment, the CD or EP gauges correspond to data points where the reference axis (e.g., the axis A-A or B-O shown in FIGS. 4, 5A and 5B) intersects the contour 814 and, more specifically, the gauges are the data points where the reference axis respectively intersect the contour 812 such that the geometric dimensions can be determined. The EP gauges 816 and CD gauges 818 are shown in FIG. 8 associated with the contour 814 in the aerial image 810, wherein each of the EP gauges 816 forms in a cross shape, and each of the CD gauges forms in an X shape. As can be seen in FIG. 8, some of the EP gauge 816 may overlap with the CD gauge 818 to from a six-pointed asterisk shape 819.

Referring to FIGS. 9 and 10, in some embodiments, the simulation model 640 is further configured to generate an auxiliary image 820A that illustrates the distribution of gauges in different regions on the aerial image 810. Different values may be displayed using different colors in a color bar, although FIG. 10 only shows the auxiliary image 820A with grayscale pixels for illustrational simplicity. The auxiliary image 820A may further illustrates the EP gauges 816, the CD gauges 818, and a predictive contour 822 for generating the photoresist image 830A. The simulation model 620 includes one or more machine learning algorithms therein. The auxiliary image 820A is then transmitted to an image processor 660.

In some embodiments, the simulation model 640 may be configured to generate the auxiliary image 820B. The auxiliary image 820B includes a gradient field (represented by tiny arrows) that includes a plurality of gradient vectors showing directions and amplitudes of movements from the contour 812 to a predictive contour 822. The directions and amplitudes of the gradient field may indicate the extent of variation of contour adjustment predicted by the simulation model 640.

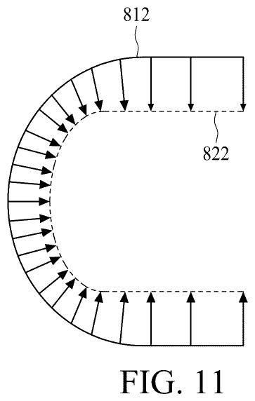

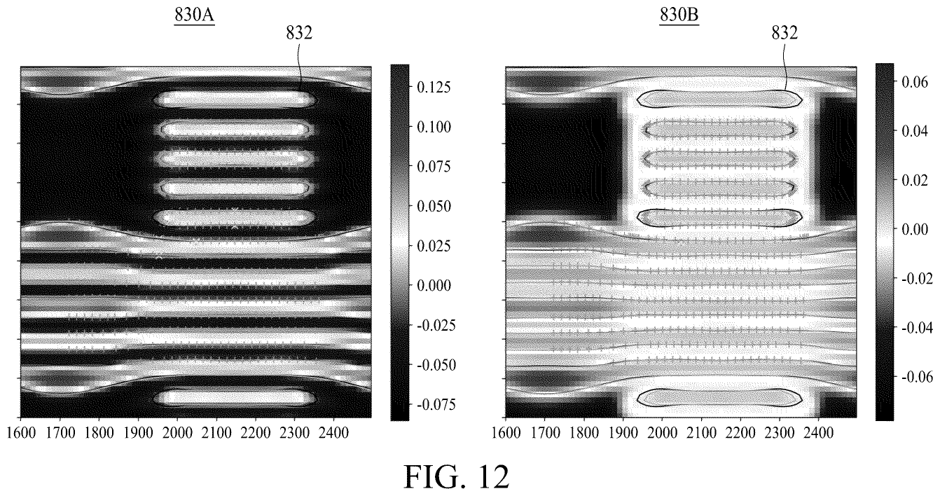

Referring to FIGS. 6, 11, and 12, the method 500 proceeds to the step S506, in which the aerial image 820A/820B is converted into a photoresist image 830A/830B. The photoresist image 830A/830B includes the predictive contour 822 (i.e., the second contour) associated with the design layout 800 according to the parameter set. The photoresist image is a two-dimensional (2D) image. In some embodiments, the photoresist image 830A/830B simulates the distribution of exposed regions and unexposed regions in the photoresist layer. The photoresist image 830A/830B may be pre-development photoresist images. The image processor 660 performs one or more image processing operations to generate the photoresist image 830A/830B. In some embodiments, the image processor 660 generates photoresist image 830A based on the auxiliary image 820A by performing at least one morphological operation. The photoresist image 830A may be a combination of the aerial image 810 and the auxiliary image 820A, e.g., by an amplitude addition of corresponding pixels in the aerial image 810 and the auxiliary image 820A.

For example, the image processor 660 performs at least one morphological operation on the auxiliary image 820A to generate the photoresist image 830A. In an embodiments, the auxiliary image 820A may be processed by a softmax function to predict the photoresist image 830A of the design layout 800. An operation of the softmax function may be applied to the auxiliary image 820A to thereby obtain the photoresist image 830A. In an example, the softmax function is applied to every pixel of the auxiliary image 820A. In some embodiments, the softmax function is given by the following equation:

$$K [ I , α ] ( x , y ) = \frac{{\sum }_{k} I ( {x}_{k} , {y}_{k} ) {e}^{α ( {x}_{k} , {y}_{k} ) I ( {x}_{k} , {y}_{k} )}}{{\sum }_{k} {e}^{α ( {x}_{k} , {y}_{k} ) I ( {x}_{k} , {y}_{k} )}} .$$

In the above equation, K represents the amplitude of the (x,y)-th pixel in the auxiliary image 820A, k represents the pixel index within a convolution window, alpha represents the parameter set provided by the optical simulator 620, I represent the optical intensity, and arguments (x, y) represent the coordinates of a pixel in the aerial image 820A. In another example, the auxiliary image 820A may be processed by a power mean function to predict the photoresist image 830A of the design layout 800. An operation of the power mean function may be applied to the auxiliary image 820A to thereby obtain the photoresist image 830A. In an example, the power mean function is applied to every pixel of the auxiliary image 820A. In some embodiments, the power mean function is given by the following equation:

$$K [ I , α ] ( x , y ) = {( \frac{1}{n} {\sum }_{k} {I ( {x}_{k} , {y}_{k} )}^{α ( x , y )} )}^{\frac{1}{α ( x , y )}}$$

In the above equation, k represents the pixel index within a convolution window, alpha represents the parameter set provided by the optical simulator 620, I represent the optical intensity, n represents the number of pixels in a convolution window, and arguments (x, y) represent the coordinates of a pixel in the aerial image.

In another example, the auxiliary image 820A may be processed by a Lehmer method to predict the photoresist image 830A of the design layout 800. An operation of Lehmer mean may be applied to the auxiliary image 820A to thereby obtain the photoresist image 830A. In an example, the Lehmer function is applied to every pixel of the auxiliary image 820A. In some embodiments, the Lehmer function is given by the following equation:

$$K [ I , α ] ( x , y ) = \frac{{\sum }_{k} {I ( {x}_{k} , {y}_{k} )}^{α ( {x}_{k} , {y}_{k} )}}{{\sum }_{k} {I ( {x}_{k} , {y}_{k} )}^{α ( {x}_{k} , {y}_{k} ) - 1}}$$

In the above equation, k represents the pixel index within a convolution window, alpha represents the parameter set provided by the optical simulator 620, I represent the optical intensity, and arguments (x, y) represent the coordinates of a pixel in the aerial image 820A.

In alternative embodiments, the image processor 660 generates the photoresist image 830B based on the auxiliary image 820B by performing a gradient-based operation. The image processor 660 simulates the photoresist image 830B in an iterative manner, and the photoresist image 830B is generated at the end of the iteration. The photoresist image 830B may be a combination of the aerial image 810 and the auxiliary 820B. For example, the photoresist image 830B may be generated using the following formula:

$$\frac{\partial I ( t , x , y )}{\partial t} = α ( t , x , y ) \cdot ∇ I ( t , x , y ) ,$$

in which I(t=0,x,y) represents the pixel value of the (x,y)-th pixel of the aerial image 810, I(t=T,x,y) represents pixel value of the (x,y)-th pixel of the photoresist image 830B, the argument t represents a time index, and arguments (x, y) represent the coordinates of a pixel in the aerial image 810.

After obtaining the photoresist images 830A/830B, a determination may be made whether an error (e.g., CD error and EP errors) between the photoresist image 830A/830B and the design layout 800 is within a specification. If the error between the photoresist image 830A/830B and the design layout 800 is within the specification, the design layout 800 is transmitted to the mask house 120 shown in FIG. 1, and a mask comprising the design layout 800 is manufactured. The manufactured mask is transmitted to the fab 130, and a lithography operation is presorted on a workpiece using the mask. If the error between the photoresist image 830A/830B and the design layout 800 is within the specification, the design layout 800 will be modified, and the method 500 shown in FIG. 6 is performed until the modified design layout 800 complies with the manufacturing specifications.

The method 500 may be performed at a design house (such as the design house 110 shown in FIG. 1). In some embodiments, the method 800 may be performed at a design house (such as the design house 110 shown in FIG. 1) in order to qualify a proposed design layout of a mask. Layout verification using simulated photoresist image 830A/830B generated using EP and CD gauges results in significant time and cost savings by virtue of not requiring exposure, development, and metrology of actual wafers. It also provides a quantifiable basis for mask and OPC quality control as well as the ability to proactively predict operation corrections that will optimize the manufacture of a device design for the mask.

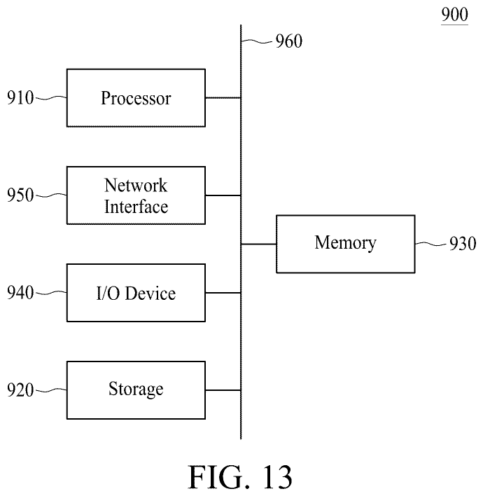

FIG. 13 is a schematic diagram of a system 900 for implementing the semiconductor fabrication methods discussed above, in accordance with some embodiments. Referring to FIG. 13, the system 900 includes one or more processors 910, a storage device 920, a memory 930, an input and output (I/O) device 940, a network interface 950, and a bus 960. The bus 960 couples the processor(s) 910, the storage device 920, the memory 930, the I/O device 940, the network interface 950 to each other.

The processor(s) 910 is/are configured to execute program instructions that include a tool configured to perform the method as described and illustrated with reference to figures of the present disclosure. Accordingly, the tool is configured to execute the steps, such as generating aerial image, identifying contours in the aerial image, determining parameter set from training data, and generating the photoresist image.

The storage device 920 is configured for storing program instructions and data accessed by the program instructions. In some embodiments, the storage device 920 includes a non-transitory computer-readable storage medium, for example, a magnetic disk and an optical disk.

The memory 930 is configured to store program instructions to be executed by the processor(s) 910 and data accessed by the program instructions. In some embodiments, the memory 930 includes any combination of a random access memory (RAM), some other volatile storage device, a read-only memory (ROM), and some other non-volatile storage device.

The network interface 950 is configured to access program instructions and data accessed by the program instructions stored remotely through a network (not shown).

The I/O device 940 includes an input device and an output device configured for enabling user interaction with the system 900. In some embodiments, the input device includes, for example, a keyboard, a mouse, and other devices. Moreover, the output device includes, for example, a display, a printer, and other devices.

In accordance with some embodiments of the present disclosure, a method includes receiving an aerial image associated with a design layout, wherein the aerial image comprises a first contour corresponding to the design layout; determining a parameter set associated with the first contour based on a simulation model; and converting the aerial image into a photoresist image comprising a second contour associated with the design layout according to the parameter set.

In accordance with some embodiments of the present disclosure, a non-transitory computer-readable storage medium, including instructions which, when executed by a processor, perform the steps of: receiving an aerial image associated with a design layout, wherein the aerial image comprises a first contour corresponding to a metal line pattern; determining, using a simulation model, a parameter set associated with the first contour based on historical data; generating an auxiliary image comprising a second contour associated with the designed layout in accordance with the modeling parameters; and converting the aerial image to a photoresist image based on the auxiliary image.

In accordance with some embodiments of the present disclosure, a system, including a processor and one or more programs including instructions which, when executed by the processor, cause the system to: receive an aerial image associated with a design layout of a lithography mask, wherein the aerial image comprises a first contour corresponds to the design layout; apply a neural network to the aerial image to generate a parameter set associated with the first contour based on historical data; and convert the aerial image to a photoresist image comprising a second contour in based on the parameter set.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving an aerial image associated with a design layout, wherein the aerial image comprises a first contour corresponding to the design layout;
determining a parameter set associated with the first contour based on a simulation model; and
converting the aerial image into a photoresist image comprising a second contour associated with the design layout according to the parameter set.

2. The method according to claim 1, further comprising generating an auxiliary image comprising the first contour and the second contour.

3. The method according to claim 2, wherein the auxiliary image further comprises a gradient field that includes a plurality of gradient vectors showing movements from a plurality of first sample points of the first contour to a plurality of second sample points of the second contour.

4. The method according to claim 3, wherein the photoresist image is simulated by using a gradient-based equation.

5. The method according to claim 4, wherein the gradient-based equation is given by:
$$\frac{\partial ( t , x , y )}{\partial t} = α ( t , x , y ) \cdot ∇ I ( t , x , y ) ,$$
in which I(t=0,x,y) represents the aerial image, the I(t=T,x,y) represents the photoresist image, the argument t represents a time index, and the arguments (x, y) represent the coordinates of a pixel in the aerial image.

6. The method according to claim 1, wherein the photoresist image is simulated using a morphology-based operation.

7. The method according to claim 6, wherein the photoresist image is a result of a function given by:
$$K [ I , α ] ( x , y ) = \frac{{\sum }_{k} I ( {x}_{k} , {y}_{k} ) {e}^{α ( {x}_{k} , {y}_{k} ) I ( {x}_{k} , {y}_{k} )}}{{\sum }_{k} {e}^{α ( {x}_{k} , {y}_{k} ) I ( {x}_{k} , {y}_{k} )}} .$$

8. The method according to claim 1, further comprising performing a training on the simulation model using historical data of design layouts and photoresist images corresponding to the design layout.

9. The method according to claim 8, wherein the parameter set comprises information on the changes in critical dimensions and edge placements of historical contours.

10. The method according to claim 1, wherein the parameter set identifies the distribution of gauges in different regions on the aerial image in order to predict the movement of the first contour.

11. The method according to claim 1, wherein the photoresist image is a pre-development photoresist image.

12. The method according to claim 1, further comprising manufacturing a lithographic mask according to the design layout in response to determining that the photoresist image complies with a specification.

13. The method according to claim 12, further comprising performing a lithography operation on a workpiece using the lithographic mask.

14. A non-transitory computer-readable storage medium, comprising instructions which, when executed by a processor, perform the steps of:
receiving an aerial image associated with a design layout, wherein the aerial image comprises a first contour corresponding to a metal line pattern;
determining, using a simulation model, a parameter set associated with the first contour based on historical data;
generating an auxiliary image comprising a second contour associated with the designed layout in accordance with the modeling parameters; and
converting the aerial image to a photoresist image based on the auxiliary image.

15. The non-transitory computer-readable storage medium according to claim 14, wherein the determination of the parameter set comprises:
calculating a plurality of edge placement errors and a plurality of critical dimension errors for the first contour; and
determining a gradient variation between the first contour and the second contour.

16. The non-transitory computer-readable storage medium according to claim 14, wherein the historical data comprising a design parameter sets of a lithography mask and a photoresist pattern interacted with the lithography mask.

17. The non-transitory computer-readable storage medium according to claim 14, further comprising determining whether an error between the photoresist image and the design layout is within a specification.

18. A system, comprising a processor and one or more programs including instructions which, when executed by the processor, cause the system to:
receive an aerial image associated with a design layout of a lithography mask, wherein the aerial image comprises a first contour corresponds to the design layout;
apply a neural network to the aerial image to generate a parameter set associated with the first contour based on historical data; and
convert the aerial image to a photoresist image comprising a second contour in based on the parameter set.

19. The system according to claim 18, wherein the instructions, when executed by the processor, further cause the system to generate an auxiliary image comprising the second contour based on the parameter set.

20. The system according to claim 18, wherein the parameter set are determined according to a plurality of edge placement gauge errors and a plurality of critical dimension gauge errors between historical design layouts and a photoresist pattern corresponding to the historical design layouts.
